(19) United States
(12) Patent Application Publication
(10) Pub. No.: US 2019/0062903 A1
(43) Pub. Date: Feb. 28, 2019

(54) WEB SUBSTRATE TREATING SYSTEM

(71) Applicant: VNI SOLUTION CO., LTD., Gyeonggi-do (KR)

(72) Inventor: Saeng Hyun CHO, Gyeonggi-do (KR)

(73) Assignee: VNI Solution Co., Ltd., Daejeon (KR)

(21) Appl. No.: 15/761,780

(22) PCT Filed: Sep. 21, 2015
(86) PCT No.: PCT/KR2015/009875

§ 371 Date: Mar. 20, 2018

(51) Int. Cl. C23C 14/56; C23C 16/54

(52) U.S. Cl. CPC C23C 14/566; C23C 16/545

(57) ABSTRACT

The objective of the present invention is to provide a web substrate treating system that allows a web substrate to be wound around, or unwound from, a roller in a direction perpendicular to the ground to prevent particles, arcing, and the like. The present invention provides a web substrate treating system comprising: a loading roller (100) around which a web substrate (W) to be treated is wound; at least one rotary drum (200) that rotates to convey the web substrate (W) unwound from the loading roller (100) while supporting the web substrate (W); an unloading roller (300) around which the web substrate (W) treated via the rotary drums (200) is wound; and substrate treating units (400) arranged around the rotary drum (200) to treat the web substrate (W) conveyed while being supported on the outer circumferential surface of the rotary drum (200), whereby it is possible to prevent particles, arcing, and the like.

### TECHNICAL FIELD

The present invention relates to a web substrate treating system and, particularly, to a web substrate treating system configured to perform substrate treatment such as a deposition process on a web substrate wound on a roll.

### BACKGROUND ART

The web substrate treating system refers to an apparatus which includes a pair of rollers, a plasma generator between the pair of rollers, and the like, and performs substrate treatment while being moved from one of the rollers to the other one of the rollers by rotation of the rollers.

An example of a conventional web substrate treating system includes Korean Patent Publication Application No. 10-2007-0106462.

The conventional web substrate treating system includes a pair of rollers 1 and 2 arranged horizontally and a cathode 7 and an anode 8 disposed between the pair of rollers 1 and 2 as shown in FIG. 1 of Korean Patent Publication Application No. 10-2007-0106462.

However, the conventional web substrate treating system has the following problems occurring when a web substrate is transferred in a horizontal state.

Firstly, a web substrate sags between a pair of rollers, and thus the web substrate cannot be uniformly treated.

Secondly, particles, which are generated while the substrate treatment such as deposition is performed on an upper surface or a lower surface of a web substrate, may cause defective substrate treatment, for example, may cause damage to the surface of the web substrate or generation of arcing.

Thirdly, a pair of rollers, a cathode 7, and an anode 8, which are arranged in a line, may increase the space occupied by a device including them, and makes it difficult to maintain or repair the device.

### DETAILED DESCRIPTION OF THE INVENTION

### Technical Problem

Therefore, the present invention has been made in view of the above-mentioned problems, and an aspect of the present invention is to provide a web substrate treating system which can prevent problems, such as generation of particles and generation of arcing, by allowing a web substrate to be unwound from or wound on a roller and a rotary drum.

### Technical Solution

In order to solve the problems described above, the present invention provides a web substrate treating system including: a loading roller 100 on which a web substrate (W) to be treated is wound; at least one rotary drum 200 configured to rotate to transfer the web substrate (W) while supporting the web substrate (W) unwound from the loading roller 100; an unloading roller 300 on which the web substrate (W) having been treated through the rotary drum 200 is wound; and substrate treating units 400 arranged along a circumferential direction of the rotary drum 200 to treat the web substrate (W) which rotates while being supported on an outer circumferential surface of the rotary drum 200.

Each of the loading roller 100, the unloading roller 300, and the rotary drum 200 may have a rotary shaft disposed vertically or horizontally with respect to the ground.

In the case where the rotary shafts of the loading roller 100, the unloading roller 300, and the rotary drum 200 are arranged vertically with respect to the ground, the web substrate (W) can be stably transferred.

In the case where the rotary shafts of the loading roller 100, the unloading roller 300, and the rotary drum 200 are arranged horizontally with respect to the ground, the web substrate (W) can be stably treated.

The web substrate treating system may include a plurality of rotary drums 200, and a pair of pressure rollers 460 arranged to be spaced apart by a distance smaller than the diameter of the rotary drums 200 and installed between the loading roller 100 or the unloading roller 300 and the rotary drums 200 and between the plurality of rotary drums 200, so as to maintain a state in which the web substrate (W) is in close contact with the outer circumferential surfaces of the rotary drums 200.

A plurality of modules constituting the substrate treating unit 400 may be installed due to the installation of the plurality of rotary drums 200, so that a large number of substrates can be treated and a substrate can be variously treated.

Furthermore, the substrate treatment is performed by the rotary drum 200 having a rotary shaft perpendicular to the ground. Therefore, although a web substrate (W) can be rotated, a large number of web substrates (W) can be treated, and a web substrate can be variously treated, the space occupied by a device including the rotary drum can be significantly reduced, and the web substrate treating system has advantages of good footprint and reduced manufacturing costs.

According to an aspect of the present invention, the web substrate treating system may include a load lock chamber 410 configured to replace a web substrate (W) and a process chamber 420 configured to perform substrate treatment, wherein the loading roller 100 and the unloading roller 300 may be installed in the load lock chamber 410, and the rotary drum 200 and the substrate treating unit 400 may be installed in the process chamber 420.

According to an aspect of the present invention, the load lock chamber 410 and the process chamber 420 are separated from each other with a partition wall 450 disposed therebetween so as to enable the web substrate (W) to be introduced and discharged while maintaining the airtightness of the process chamber 420. The partition wall may include sealing rollers 440 configured to allow the web substrate (W) to pass through the load lock chamber 410 or the process chamber 420 while being in close contact with the web substrate (W).

According to an aspect of the present invention, the loading roller 100, the unloading roller 300, and the rotary drum 200 may be disposed such that the rotary shafts thereof are perpendicular to the ground.

The substrate treating unit 400 may include at least one of a sputter module for a sputtering process, an atomic layer deposition module for an atomic layer deposition process, an evaporation module for an evaporation deposition process, a monolayer deposition module for a monolayer deposition process, a CVD module for a CVD process, and an ICP module for an ICP process.

The substrate treating unit 400 includes at least two modules among the sputter module for a sputtering process, the atomic layer deposition module for an atomic layer deposition process, the evaporation module for an evaporation deposition process, the monolayer deposition module for a monolayer deposition process, the CVD module for a CVD process, and the ICP module for an ICP process, and the at least two modules are arranged along the circumferential direction of the rotary drum 200.

In the substrate treating unit 400, at least two modules for substrate treatment are arranged along the circumferential direction of the rotary drum 200, so that the space occupied by a device including the modules can be remarkably reduced to have good footprint, and manufacturing costs thereof can be reduced.

### Advantageous Effects

A web substrate treating system according to an embodiment of the present invention can prevent generation of particles, generation of arcing, and the like by allowing a web substrate to be unwound from or wound on a roller while being perpendicular to the ground.

According to an aspect of the present invention, the web substrate treating system includes a rotary drum which rotates while supporting a web substrate unwound from a loading roller, thereby performing substrate treatment in a state in which the web substrate is stably supported and thus enabling more stable substrate treatment.

According to another aspect of the present invention, a plurality of substrate treating units 400 are arranged along the circumferential direction of a rotary drum which rotates while supporting a web substrate unwound from a loading roller, so that a plurality of substrates can be treated.

According to another aspect of the present invention, a plurality of substrate treating units 400 are arranged along the circumferential direction of a rotary drum which rotates while supporting a web substrate unwound from a loading roller, so that the space occupied by a device including the plurality of substrate treating units can be significantly reduced, and the substrate treating units 400 are arranged along the circumferential direction of the rotary drum, whereby the maintenance and repairing thereof is easy.

### BRIEF DESCRIPTION OF THE DRAWINGS

FIG. 1 is a plan sectional view of a web substrate treating system according to a first embodiment of the present invention;

FIG. 2 is a side view illustrating a part of the web substrate treating system shown in FIG. 1; and

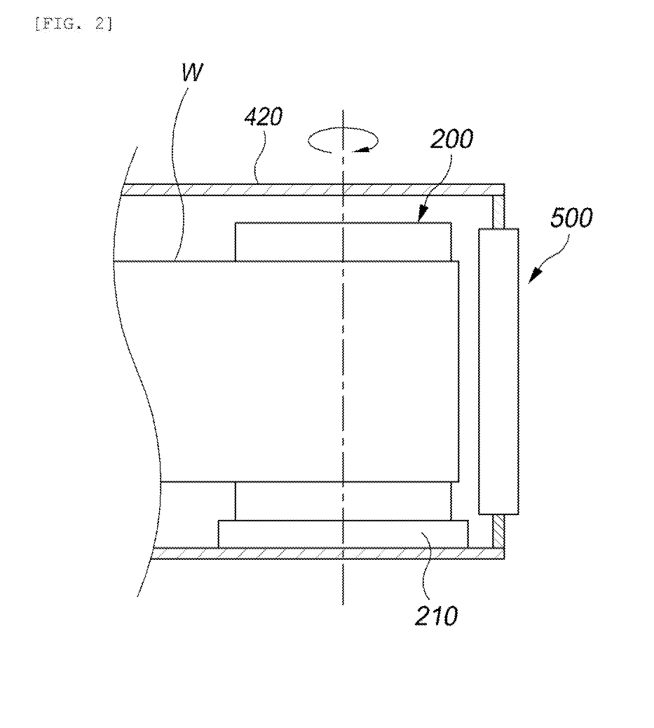

FIG. 3 is a plan sectional view of a web substrate treating system according to a second embodiment of the present invention.

### MODE FOR CARRYING OUT THE INVENTION

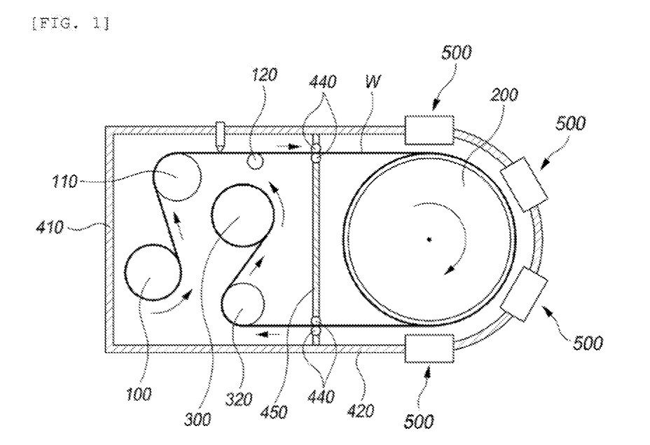

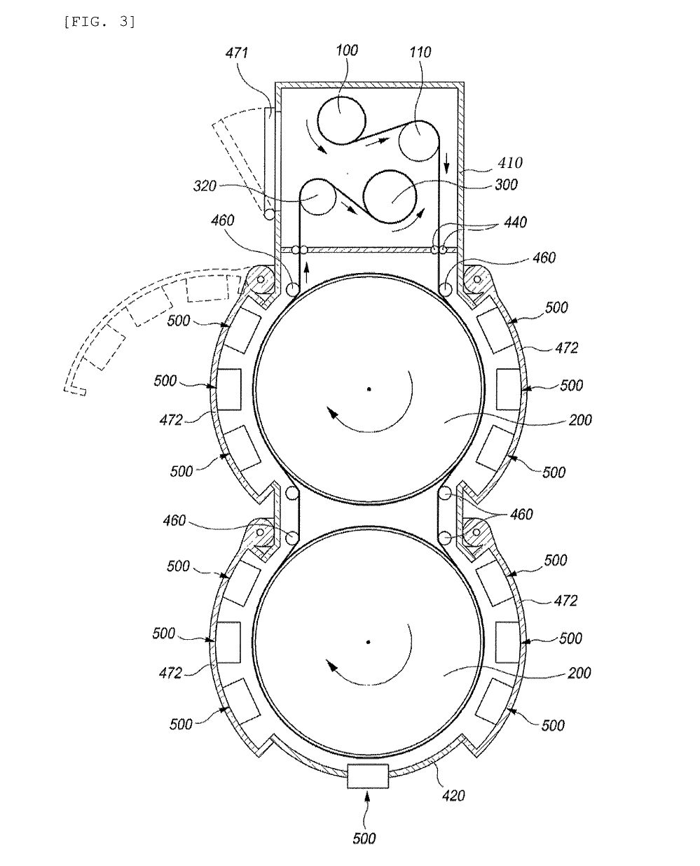

Hereinafter, embodiments of the present invention will be described with reference to the accompanying drawings. FIG. 1 is a plan sectional view of a web substrate treating system according to a first embodiment of the present invention, and FIG. 3 is a plan sectional view of a web substrate treating system according to a second embodiment of the present invention.

As described in FIG. 1, a web substrate treating system according to an embodiment of the present invention includes: a loading roller 100 on which a web substrate (W) to be treated is wound; at least one rotary drum 200 configured to rotate to transfer the web substrate (W) while supporting the web substrate (W) unwound from the loading roller 100; an unloading roller 300 on which the web substrate (W) having been treated through the rotary drum 200 is wound; and substrate treating units 400 arranged along a circumferential direction of the rotary drum 200 to treat the web substrate (W) which rotates while being supported on an outer circumferential surface of the rotary drum 200.

The web substrate (W) may be a member on which substrate treatment such as deposition is performed, and may be any member that can be bent, such as a general industrial film used as a flexible OLED film, a wrapping paper, a cover member, a protective film, and the like.

In particular, the flexible OLED film may include an organic film, an inorganic film, or the like by the web substrate treating system according to an embodiment of the present invention, and may be used as a substrate for an OLED TV or a planar illumination.

In a general industrial film, an inorganic film layer, a metal layer, or the like may be formed by the web substrate treating system according to an embodiment of the present invention so as to increase the surface strength or prevent the formation of scratches, so that the service life of the film can be extended.

The loading roller 100 is a roller, on which a web substrate (W) to be treated is wound, is disposed in a load lock chamber 410 in a state in which a rotary shaft of the loading roller is perpendicular or horizontal to the ground, and is rotated by rotation of a rotation driving unit (not shown), so that the web substrate (W) is unwound from the loading roller and is moved toward the rotary drum 200.

The unloading roller 300 is a roller, on which the web substrate (W) having been treated through the rotary drum 200 is wound, is disposed in the load lock chamber 410 in a state in which a rotary shaft of the unloading roller is perpendicular or horizontal to the ground, and is rotated by rotation of the rotation driving unit (not shown), so that the web substrate (W) having been treated through the rotary drum 200 is wound on the unloading roller.

In order to protect the substrate-treated surface when the web substrate (W) is wound on the unloading roller 300, the web substrate may be configured to be wound on the unloading roller while a protective film wound on a buffer roller (not shown) adjacent thereto is attached to the surface.

The rotary drum 200 is a component which is rotated by rotation of the rotation driving unit 210 while supporting the web substrate (W) unwound from the loading roller 100 to transfer the web substrate (W). The rotary drum is disposed in a process chamber 420 in a state in which a rotary shaft of the rotary drum is perpendicular or horizontal to the ground.

The rotary drum 200 may have a diameter of a proper size to enable substrate treatment by a substrate support unit described later, and may be variously configured by including an electrode member connected to the configuration of the substrate treating unit 400, or the like.

Further, the web substrate treating system may include one rotary drum 200, or may include a plurality of rotary drums 200 to enable a plurality of substrates to be easily treated.

A pair of pressure rollers 460 arranged to be spaced apart by a distance smaller than the diameter of the rotary drums 200 may be installed between the loading roller 100 or the unloading roller 300 and the rotary drums 200 and between the rotary drums 200, so as to maintain a state in which the web substrate (W) is in close contact with the outer circumferential surfaces of the rotary drums 200.

The pair of pressure rollers 460 are arranged to be spaced apart by a distance smaller than the diameter of the rotary drums 200 so as to maintain a state in which the web substrate (W) is in close contact with the outer circumferential surface of the rotary drum 200, so that the web substrate (W) comes into close contact with the outer circumferential surfaces of the rotary drums 200.

The appropriate numbers of the pair of pressure rollers 460 may be installed at appropriate positions according to the degree of close contact of the web substrate (W) to the rotary drum 200.

The substrate treating unit 400 is a component which is disposed along the circumferential direction of the rotary drum 200 and is configured to treat the web substrate (W) which rotates while being supported on the outer circumferential surface of the rotary drum 200. Various configurations of the substrate treating unit are possible depending on the type of substrate treatments and the number of substrates to be treated.

The substrate treating unit 400 may include at least one of a sputter module for a sputtering process, an Atomic Layer Deposition (ALD) module for an atomic layer deposition process, an evaporation module for an evaporation deposition process, a Monolayer Deposition (MLD) module for a monolayer deposition process, a CVD module for a CVD process, and an ICP module for an ICP process.

In the case where the substrate treating unit 400 includes the sputter module for a sputtering process, the sputter module may include a cathode and a target electrode, and a gas injection unit configured to inject gas between the cathode and the target electrode.

In the case where the substrate treating unit 400 includes the atomic layer deposition module, the atomic layer deposition module may be configured as a component configured to perform an atomic layer deposition process, as described in Korean Patent Publication Application No. 10-2012-0109989.

In the case wherein the substrate treating unit 400 includes the evaporation module for an evaporation deposition process, the substrate treating unit 400 may include a linear evaporation source configured to evaporate a deposition material along the longitudinal direction of the rotary drum 100.

The substrate treating unit 400 may further include an ultraviolet ray irradiation device configured to cure a web substrate (W) on which at least one deposition material of organic and inorganic materials is deposited.

In the case where the substrate treating unit 400 includes the monolayer deposition (MLD) module for a monolayer deposition process, the monolayer deposition (MLD) module may include a gas injection unit configured to inject a precursor for the deposition of monolayer deposition (MLD).

In the case where the substrate treating unit 400 includes the CVD module for a CVD process, the substrate treating unit 400 may include a gas injection unit spaced apart from the outer circumferential surface of the rotary drum 200 so as to apply RF power to the rotary drum 200 or ground the rotary drum 200 and inject treating gas according to the configurations of an upper electrode and a lower electrode.

In the case where the substrate treating unit 400 includes the ICP module for an ICP process, the ICP module may include a dielectric and an antenna which is opposite to the rotary drum 200 with the dielectric disposed therebetween to form an induced electric field.

The substrate treating unit 400 may include one of the modules described above, or may include the same module or different modules, which are disposed in an appropriate number along the circumferential direction of the rotary drum 200.

In particular, the substrate treating unit 400 may include as many modules as possible to enable a large number of substrates to be treated, and an appropriate number of rotary drums 200 are installed so that a large number of modules can be installed.

The web substrate treating system according to an embodiment of the present invention may include a load lock chamber 410 configured to replace a web substrate (W) for installation of the loading roller 100, the unloading roller 300, and the rotary drum 300, and a process chamber 420 configured to perform substrate treatment.

The load lock chamber 410 includes the loading roller 100, the unloading roller 300, and a door 471 which is installed so that after substrate treatment is completed, the loading roller 100 on which a new web substrate is wound can be introduced, and the unloading roller 100 by which the substrate treatment is completed can be taken out to the outside.

The door 471 can be variously configured to open or close the load lock chamber 410. The door may be sealed to maintain the degree of vacuum after the door 471 is closed.

The process chamber 420 can be variously configured as a component in which the rotary drum 200 and the substrate treating unit 400 are installed.

The process chamber 420 may include a door 472 as shown in FIG. 3 for maintenance and repairing of the rotary drum 200 and the substrate treating unit 400.

The door 472 closes the process chamber 420 during a process, and opens the process chamber 420 for maintenance and repairing of the rotary drum 200 and the substrate treating unit 400.

The substrate treating unit 400 may be configured to be installed on the door 472 so that the substrate treating unit 400 is moved together when the door 472 is opened, so as to facilitate maintenance and repairing thereof.

The load lock chamber 410 and the process chamber 420 are separated from each other with a partition wall 450 disposed therebetween so as to enable the web substrate (W) to be introduced and discharged while maintaining the airtightness of the process chamber 420. The partition wall may include sealing rollers 440 configured to allow the web substrate (W) to pass through the load lock chamber 410 or the process chamber 420 while being in close contact with the web substrate (W).

The load lock chamber 410 and the process chamber 420 may include auxiliary rollers 110 and 320 configured to rotate while supporting the web substrate (W) to change a movement path of the web substrate (W) and maintain tension.

The partition wall 450 is a component configured to separate the load lock chamber 410 and the process chamber 420. The partition wall may be configured as a part of the outer wall of the process chamber 420, or when the load lock chamber 410 and the process chamber 420 are configured as one chamber, the partition wall may be configured as a wall configured to partition the load lock chamber 410 and the process chamber 420.

The sealing roller 440 can be variously configured as a component configured to allow the web substrate (W) to pass through the load lock chamber 410 or the process chamber 420 by rotation in a state of being in close contact with the web substrate (W).

Each of the load lock chamber 410 and the process chamber 420 includes an exhaust pipe connected thereto and connected to a vacuum pump (not shown) in order to maintain/covert pressure or exhaust air for forming process conditions therein.

1. A web substrate treating system comprising:
a loading roller (100) on which a web substrate (W) to be treated is wound;
at least one rotary drum (200) configured to rotate to transfer the web substrate (W) unwound from the loading roller (100) while supporting the web substrate (W);
an unloading roller (300) on which the web substrate (W) having been treated through the rotary drum (200) is wound; and
substrate treating units (500) arranged along a circumferential direction of the rotary drum (200) to treat the web substrate (W) which rotates while being supported on an outer circumferential surface of the rotary drum (200).

2. The system of claim 1, wherein each of the loading roller (100), the unloading roller (300), and the rotary drum (200) has a rotary shaft disposed vertically or horizontally with respect to the ground.

3. The system of claim 1, comprising:
a plurality of rotary drums (200); and
a pair of pressure rollers (460) arranged to be spaced apart by a distance smaller than the diameter of the rotary drums (200) and installed between the loading roller (100) or the unloading roller (300) and the rotary drums (200) and between the rotary drums (200), so as to maintain a state in which the web substrate (W) is in close contact with outer circumferential surfaces of the rotary drums (200).

4. The system of claim 1, comprising:
a load lock chamber (410) configured to replace the web substrate (W); and
a process chamber (420) configured to perform substrate treatment,
wherein the loading roller (100) and the unloading roller (300) are installed in the load lock chamber (410), and the rotary drum (200) and the substrate treating units (500) are installed in the process chamber (420).

5. The system of claim 1, wherein the load lock chamber (410) and the process chamber (420) are separated from each other with a partition wall (450) disposed therebetween so as to enable the web substrate (W) to be introduced and discharged while maintaining the airtightness of the process chamber (420), and the partition wall includes sealing rollers (440) configured to allow the web substrate (W) to pass through the load lock chamber (410) or the process chamber (420) while being in close contact with the web substrate (W).

6. The system of claim 1, wherein each of the substrate treating units (500) includes at least one of a sputter module for a sputtering process, an atomic layer deposition module for an atomic layer deposition process, an evaporation module for an evaporation deposition process, a monolayer deposition module for a monolayer deposition process, a CVD module for a CVD process, and an ICP module for an ICP process.

7. The system of claim 1, wherein each of the substrate treating units (500) includes at least two modules among the sputter module for a sputtering process, the atomic layer deposition module for an atomic layer deposition process, the evaporation module for an evaporation deposition process, the monolayer deposition module for a monolayer deposition process, the CVD module for a CVD process, and the ICP module for an ICP process, and the at least two modules are arranged along the circumferential direction of the rotary drum (200).

8. The system of claim 2, wherein each of the substrate treating units 500 includes at least one of a sputter module, an atomic layer deposition module, an evaporation module, a monolayer deposition module, a CVD module, and an ICP module.

9. The system of claim 3, wherein each of the substrate treating units 500 includes at least one of a sputter module, an atomic layer deposition module, an evaporation module, a monolayer deposition module, a CVD module, and an ICP module.

10. The system of claim 4, wherein each of the substrate treating units 500 includes at least one of a sputter module, an atomic layer deposition module, an evaporation module, a monolayer deposition module, a CVD module, and an ICP module.

11. The system of claim 5, wherein each of the substrate treating units 500 includes at least one of a sputter module, an atomic layer deposition module, an evaporation module, a monolayer deposition module, a CVD module, and an ICP module.

12. The system of claim 2, wherein each of the substrate treating units 500 includes at least two modules among the sputter module, the atomic layer deposition module, the evaporation module, the monolayer deposition module, the CVD module, and the ICP module, and the at least two modules are arranged along the circumferential direction of the rotary drum (200).

13. The system of claim 3, wherein each of the substrate treating units 500 includes at least two modules among the sputter module, the atomic layer deposition module, the evaporation module, the monolayer deposition module, the CVD module, and the ICP module, and the at least two modules are arranged along the circumferential direction of the rotary drum (200).

14. The system of claim 4, wherein each of the substrate treating units 500 includes at least two modules among the sputter module, the atomic layer deposition module, the evaporation module, the monolayer deposition module, the CVD module, and the ICP module, and the at least two modules are arranged along the circumferential direction of the rotary drum (200).

15. The system of claim 5, wherein each of the substrate treating units 500 includes at least two modules among the sputter module, the atomic layer deposition module, the evaporation module, the monolayer deposition module, the CVD module, and the ICP module, and the at least two modules are arranged along the circumferential direction of the rotary drum (200).

16. A web substrate treating system, comprising:
a process chamber having a first door;
a rotary drum installed in the process chamber;
at least one treating unit installed on the first door;
a load lock chamber having a second door, the load lock chamber separated from the process chamber by a partition wall disposed between the load lock chamber and the process chamber;
a loading roller installed in the load lock chamber; and
an unloading roller installed in the load lock chamber.

17. The system of claim 16, further comprising:
a pair of pressure rollers spaced apart by a distance smaller than a diameter of the rotary drum and installed between the loading roller and the rotary drum.

18. The system of claim 17, wherein the at least one treating unit includes at least one of a sputter module, an atomic layer deposition module, an evaporation module, a monolayer deposition module, a CVD module, and an ICP module.

19. The system of claim 16, further comprising:
a pair of pressure rollers spaced apart by a distance smaller than a diameter of the rotary drum and installed between the unloading roller and the rotary drum.

20. The system of claim 19, wherein the at least one treating unit includes at least one of a sputter module, an atomic layer deposition module, an evaporation module, a monolayer deposition module, a CVD module, and an ICP module.
